(19) United States
(12) Patent Application Publication
(10) Pub. No.: US 2025/0294903 A1
(43) Pub. Date: Sep. 18, 2025

(54) ELECTRONIC COMPONENT AND METHOD OF MANUFACTURING ELECTRONIC COMPONENT

(71) Applicant: CANON KABUSHIKI KAISHA, Tokyo (JP)

(72) Inventors: YOKO NAGANO, Oita (JP); HIDEKI YOSHINAGA, Oita (JP); YU KATASE, Kanagawa (JP)

(21) Appl. No.: 19/074,571

(22) Filed: Mar. 10, 2025

(30) Foreign Application Priority Data
Mar. 15, 2024 (JP) 2024-041053

(51) Int. Cl. H10F 39/00

(52) U.S. Cl. CPC H10F 39/804; H10F 39/024; H10F 39/806

(57) ABSTRACT

An electronic component includes a substrate provided with a semiconductor element, a frame body provided over the substrate, and a lid body fixed to the frame body. The frame body has a first face in contact with the substrate and a second face facing the lid body. The second face includes a first region to which the lid body is bonded, a second region located inside the first region and provided with a concave portion, and a third region located inside the second region and provided with a convex portion. A height of a tip of the convex portion is lower than a height of a bonding face between the frame body and the lid body and is higher than a height of a bottom of the concave portion.

### BACKGROUND OF THE INVENTION

### Field of the Invention

The present invention relates to an electronic component and a method of manufacturing the electronic component.

### Description of the Related Art

An electronic device such as an imaging device may be configured as an electronic component accommodated in a package in which a circuit substrate on which the electronic device is mounted, and a resin frame body are integrated.

Japanese Patent Application Laid-Open No. 2015-038920 (PTL 1) describes an imaging device configured to improve the adhesive strength between a resin frame body and a lid body by providing a protrusion on the surface of the resin frame body. Japanese Patent Application Laid-Open No. 2014-228295 (PTL 2) describes a semiconductor pressure sensor device configured to prevent a protective member of a sensor chip from brimming over a frame component by providing a concave portion on a surface of the frame component of a package.

### SUMMARY OF THE INVENTION

According to an embodiment of the present specification, there is provided an electronic component including a substrate provided with a semiconductor element, a frame body provided over the substrate so as to surround a periphery of the semiconductor element, and a lid body fixed to the frame body, wherein the frame body has a first face in contact with the substrate and a second face facing the lid body, wherein the second face of the frame body includes a first region of a frame-shape to which the lid body is bonded, a second region of a frame-shape located inside the first region and provided with a concave portion recessed toward the substrate, and a third region of a frame-shape located inside the second region and provided with a convex portion protruding toward the lid body, wherein a height of the first region with respect to the substrate is higher than a height of the second region with respect to the substrate, wherein a side face of the frame body is located outside a side face of the lid body in a cross-sectional view of the electronic component, and wherein a height of a tip portion of the convex portion with respect to the substrate is lower than a height of a bonding face between the frame body and the lid body with respect to the substrate and is higher than a height of a bottom of the concave portion with respect to the substrate.

According to another disclosure of the present specification, there is provided a method of manufacturing an electronic component including forming a frame body over a substrate provided with a semiconductor element so as to surround a periphery of the semiconductor element, and fixing a lid body to the frame body so as to close a space in which the semiconductor element is provided, wherein, in the forming the frame body, the frame body is formed by an injection molding using a first mold configured to place the substrate, a second mold configured to mold an inner face of the frame body, and a third mold configured to mold a face of the frame body facing the lid body, wherein the second mold and the third mold are separated from each other, and are enabled to change a distance to the first mold independently of each other, and wherein the third mold includes a first region of a frame shape configured to mold a face to which the lid body is bonded, and a second region of a frame shape located inside the first region and having a convex portion protruding toward the first mold more than the first region.

Further features of the present invention will become apparent from the following description of exemplary embodiments with reference to the attached drawings.

### BRIEF DESCRIPTION OF THE DRAWINGS

FIG. 1 is a schematic plan view illustrating a configuration example of an electronic component according to a first embodiment.

FIG. 2 is a schematic cross-sectional view illustrating a configuration example of the electronic component according to the first embodiment.

FIG. 3A and FIG. 3B are schematic plan views illustrating a configuration example of a substrate in the electronic component according to the first embodiment.

FIG. 4A and FIG. 4B are schematic cross-sectional views illustrating a mold used in a method of manufacturing the electronic component according to the first embodiment.

FIG. 5A and FIG. 5B are schematic cross-sectional views illustrating a mold used in the method of manufacturing the electronic component according to the first embodiment.

FIG. 6A, FIG. 6B, FIG. 6C, and FIG. 6D are cross-sectional views illustrating the method of manufacturing the electronic component according to the first embodiment.

FIG. 7A, FIG. 7B, and FIG. 7C are enlarged cross-sectional views illustrating an example of the mold used in the method of manufacturing the electronic component according to the first embodiment and the structure of a frame body manufactured using the mold.

FIG. 8A and FIG. 8B are diagrams for explaining a problem in a case where a convex portion is not provided in a third mold.

FIG. 9A and FIG. 9B are enlarged cross-sectional views illustrating another example of the mold used in the method of manufacturing the electronic component according to the first embodiment and the structure of the frame body manufactured using the mold.

FIG. 10A and FIG. 10B are enlarged cross-sectional views illustrating another example of the mold used in the method of manufacturing the electronic component according to the first embodiment and the structure of the frame body manufactured using the mold.

FIG. 11A and FIG. 11B are enlarged cross-sectional views illustrating another example of the mold used in the method of manufacturing the electronic component according to the first embodiment and the structure of the frame body manufactured using the mold.

FIG. 12 is a block diagram illustrating a schematic configuration of an equipment according to a second embodiment of the present invention.

### DESCRIPTION OF THE EMBODIMENTS

In an electronic component in which an electronic device such as an imaging device is accommodated in a package, there is a need to further reduce mixing in the package with foreign matter as pixels are reduced. However, in PTL 1 and PTL 2, no particular consideration is given to the foreign matter generated from the package, and there is a possibility that the characteristics and reliability of the electronic device deteriorate.

The following disclosure relates to a technique for suppressing mixing with foreign matter generated from a package in an electronic component in which a semiconductor element is accommodated in a package in which a substrate and a resin frame body are integrated.

The following embodiments are intended to embody the technical idea of the present invention, and do not limit the present invention. The sizes and positional relationships of members illustrated in the drawings may be exaggerated for clarity of description.

### First Embodiment

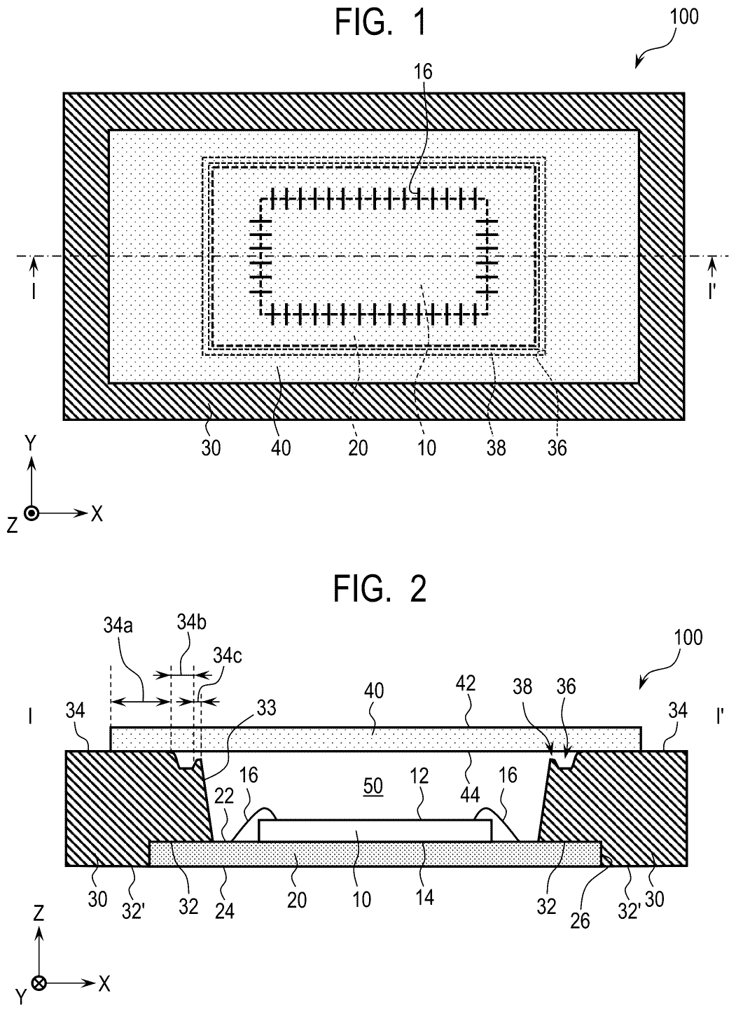

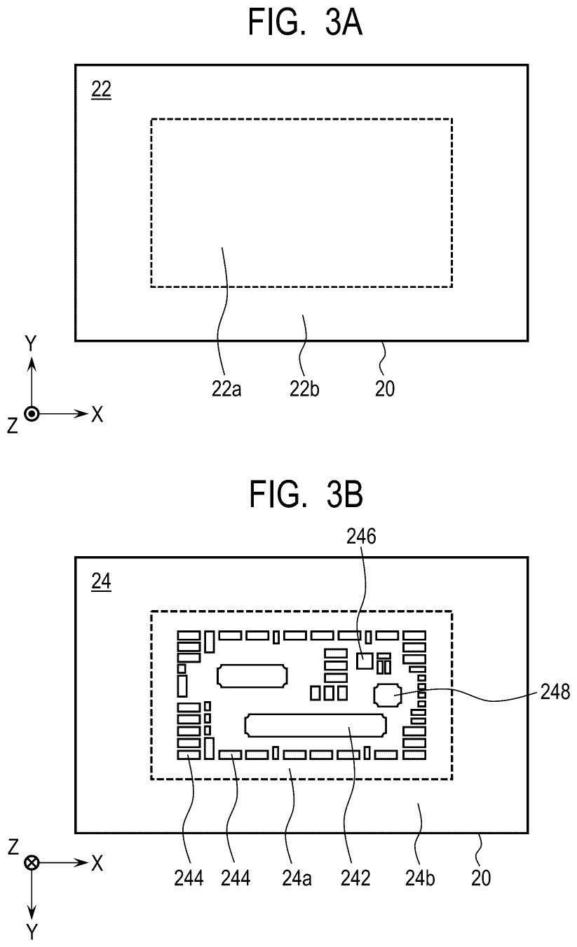

The structure of an electronic component according to a first embodiment of the present invention will be described with reference to FIG. 1 to FIG. 3B. FIG. 1 is a schematic plan view illustrating a configuration example of an electronic component according to the present embodiment. FIG. 2 is a schematic cross-sectional view illustrating a configuration example of the electronic component according to the present embodiment. FIG. 2 is a cross-sectional view taken along line I-I′ of FIG. 1. FIG. 3A and FIG. 3B are schematic plan views illustrating a configuration example of a substrate in the electronic component according to the present embodiment.

As illustrated in FIG. 1 and FIG. 2, the electronic component 100 according to the present embodiment may include a semiconductor element 10, a substrate 20, a frame body 30, and a lid body 40. Although not particularly limited, the semiconductor element 10 is, for example, a semiconductor substrate (semiconductor chip) provided with a photoelectric conversion element such as an imaging element. The substrate 20 is a part of a package that forms a cavity (internal space 50) that accommodates the semiconductor element 10 together with the frame body 30 and the lid body 40 and also serves as a mounting member for mechanically fixing the electronic component 100 and electrically connecting it to an external device. The substrate 20 is an insulating substrate made of a resin such as glass epoxy, ceramic, or the like, and is not particularly limited, but is preferably a rigid substrate. The substrate 20 may be a circuit substrate such as a printed circuit board or may further include an element other than the semiconductor element 10. The frame body 30 has a function of holding the lid body 40 apart from the substrate 20 so as to form a cavity for housing the semiconductor element 10. The lid body 40 is not particularly limited but may be formed of a light-transmissive member when the semiconductor element 10 constitutes an optical device such as a photoelectric conversion element.

The semiconductor element 10 is a plate-shaped body having a first face 12 and a second face 14 opposite to the first face 12. The substrate 20 is a plate-like body having a first face 22, a second face 24 opposite to the first face 22, and a side face 26 between the first face 22 and the second face 24. Using the coordinate system illustrated in FIG. 1 and FIG. 2, the first face 12 and the second face 14 of the semiconductor element 10 and the first face 22 and the second face 24 of the substrate 20 may be surfaces parallel to the X-Y plane. The side face 26 of the substrate 20 may be a surface parallel to the X-Z plane or the Y-Z plane. The normal direction of the first face 12 of the semiconductor element 10 and the first face 22 of the substrate 20 may be the Z direction. The normal direction of the second face 14 of the semiconductor element 10 and the second face 24 of the substrate 20 may be a direction (−Z direction) opposite to the Z direction.

The semiconductor element 10 is fixed to the central portion of the first face 22 of the substrate 20 by an adhesive (not illustrated) so that the second face 14 faces the first face 22 of the substrate 20. The semiconductor element 10 and the substrate 20 are electrically connected to each other via a plurality of bonding wires 16. For example, as illustrated in FIG. 1 and FIG. 2, each of the bonding wires 16 may be connected to a peripheral portion of the first face 12 of the semiconductor element 10. Note that the electrical connection between the semiconductor element 10 and the substrate 20 does not necessarily need to be the bonding wires 16, and solder bumps or the like may be used.

The frame body 30 has a first face (lower surface) 32 in contact with the first face 22 of the substrate 20 and a second face (upper surface) 34 facing the lid body 40. The first face 32 of the frame body 30 is bonded to the peripheral edge portion of the first face 22 of the substrate 20. For example, as illustrated in FIG. 2, the frame body 30 may be provided so as to be in contact with not only the first face 22 but also the side face 26 of the substrate 20. By providing the frame body 30 so as to be in contact with the first face 22 and the side face 26 of the substrate 20, it is possible to improve the adhesive strength between the substrate 20 and the frame body 30. In this case, a part (first face 32′) of the first face 32 of the frame body 30 may constitute one plane together with the second face 24 of the substrate 20.

The second face 34 of the frame body 30 has a frame-shaped first region 34a to which the lid body 40 is bonded, and a frame-shaped second region 34b which is located on the inner side (the side of the inner side face 33) with respect to the first region 34a and provided with a concave portion 36 recessed toward the substrate 20 side. In addition, the second face 34 of the frame body 30 further includes a frame-shaped third region 34c which is located on the inner side (the side of the inner side face 33) with respect to the second region 34b and in which the convex portion 38 protruding toward the side of the lid body 40 is provided. The concave portion 36 is provided so as to surround the third region 34c in a plan view. The third region 34c is in contact with the inner side face 33 of the frame body 30. Here, the height in the Z direction of the tip portion of the convex portion 38 provided in the third region 34c is lower than the height in the Z direction of the bonding face between the frame body 30 and the lid body 40, and higher than the height in the Z direction of the bottom surface of the concave portion 36 provided in the second region.

The lid body 40 is a flat plate-shaped member having a first face 42 and a second face 44 opposite to the first face 42. The first face 42 and the second face 44 may be surfaces parallel to the X-Y plane. The lid body 40 is fixed on the first region 34a of the second face 34 of the frame body 30 by an adhesive (not illustrated) so as to cover the space surrounded by the frame body 30 and the substrate 20. Thus, the substrate 20, the frame body 30, and the lid body 40 define an internal space 50 for accommodating the semiconductor element 10. The lid body 40 is provided so as to be spaced apart from and face the semiconductor element 10. The thickness (height in the Z direction) of the frame body 30 is larger than the thickness (height in the Z direction) of the semiconductor element 10 so that the semiconductor element 10 may be stored in the internal space 50 when the frame body 30 and the lid body 40 are disposed on the substrate 20.

The external shapes of the semiconductor element 10 and the electronic component 100 in the plan view are typically rectangular. The dimension of the electronic component 100 in the Z direction is smaller than the dimensions of the electronic component 100 in the X direction and the Y direction. That is, the electronic component 100 has a substantially flat plate shape. In this specification, the plan view means a view from the Z direction, and corresponds to, for example, the plan view of FIG. 1.

Next, a configuration example of the substrate 20 will be described in more detail with reference to FIG. 3A and FIG. 3B. FIG. 3A is a schematic plan view of the side of the first face 22 of the substrate 20, and FIG. 3B is a schematic plan view of the side of the second face 24 of the substrate 20.

The first face 22 of the substrate 20 includes a first region 22a to which the semiconductor element 10 is fixed and electrically connected, and a second region 22b to which the frame body 30 is bonded. In FIG. 3A, a rectangular region inside the broken line corresponds to the first region 22a, and a frame-shaped region outside the broken line corresponds to the second region 22b. The second region 22b surrounds the first region 22a.

Electronic elements such as connectors 242, passive components 244 such as resistors, capacitors, diodes, etc., active components 246 such as transistors, etc., and integrated circuit chips 248 may be mounted on the second face 24 of the substrate 20, as illustrated in FIG. 3B, for example. In FIG. 3B, a rectangular region on the inner side of the broken line is a first region 24a on the opposite side of the first region 22a of the first face 22, and a frame-shaped region on the outer side of the broken line is a second region 24b on the opposite side of the second region 22b of the first face 22. In the configuration example of FIG. 3B, the electronic element is mounted only in the first region 24a, but at least a part of the electronic element may be disposed in the second region 24b.

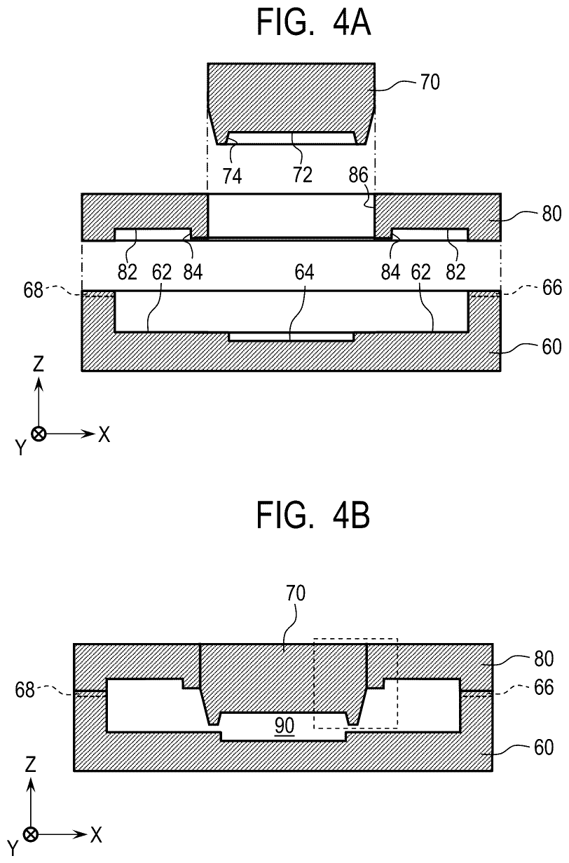

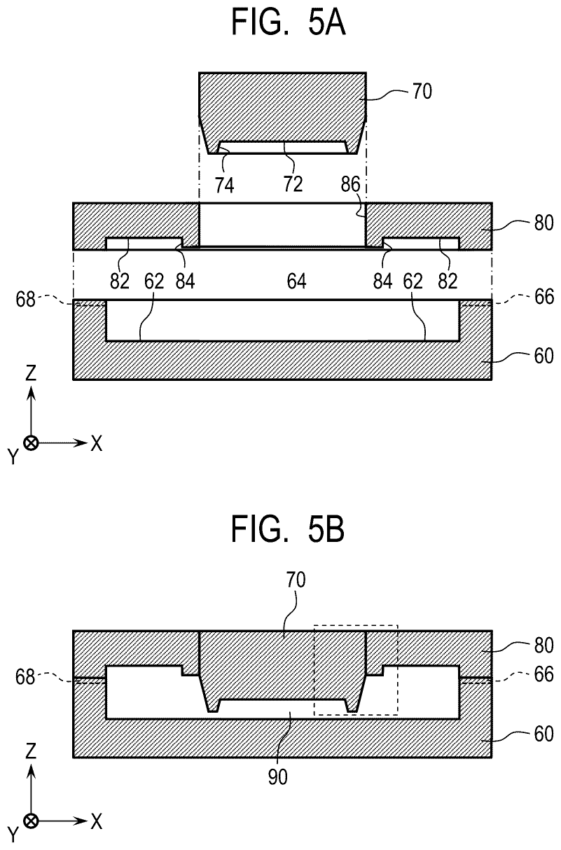

In the method of manufacturing the electronic component 100 according to the present embodiment, injection molding is used to form the frame body 30. Before describing a specific method for manufacturing the electronic component 100, a mold used for injection molding of the frame body 30 will be described with reference to FIG. 4A to FIG. 5B. FIG. 4A to FIG. 5B are schematic cross-sectional views of the mold corresponding to the cross section taken along the line I-I′ of FIG. 1. FIG. 4A and FIG. 5A illustrate a state in which the mold is opened, and FIG. 4B and FIG. 5B illustrate a state in which the mold is closed.

As illustrated in FIG. 4A to FIG. 5B, a mold used for injection molding of the frame body 30 may include a first mold 60, a second mold 70, and a third mold 80. The first mold 60 serves as a base on which the substrate 20 on which the semiconductor element 10 is mounted is placed and has a function of determining the shape of the bottom surface side (the first face 32 side) of the frame body 30 together with the substrate 20. The second mold 70 has a function of pressing and fixing the substrate 20 to the first mold 60 and determining the shape of the inner side face 33 of the frame body 30. The third mold 80 is a mold facing the first mold 60 and has a function of determining the shape of the upper surface side (the second face 34 side) of the frame body 30. The third mold 80 has an opening 86 in a central portion thereof, into which the second mold 70 is inserted. A cavity 90 is formed inside the mold by closing the mold, that is, by bringing the third mold 80 in contact with the first mold 60 and fitting the second mold 70 into the opening 86 (see FIG. 4B and FIG. 5B). The shape of the outer surface of the frame body 30 may be determined by either or both of the first mold 60 and the third mold 80.

The first mold 60 has a first face 62 facing the third mold 80 and a second face 64 facing the second mold 70. When electronic elements are mounted on the side of the second face 24 of the substrate 20, the second face 64 may be provided at a position lower than the first face 62 in the Z direction, as in the mold illustrated in FIG. 4A and FIG. 4B, in order to prevent interference with these electronic elements. When no electronic elements are mounted on the side of the second face 24 of the substrate 20, the first face 62 and the second face 64 may have the same height as in the mold illustrated in FIG. 5A and FIG. 5B. When the frame body 30 is configured to be in contact with the side face 26 of the substrate 20 as illustrated in FIG. 2, the first mold 60 may be configured such that the outer edge portion of the first face 62 is located outside the outer edge portion of the substrate 20.

The second mold 70 has a first face 72 facing the second face 64 of the first mold 60. A convex portion 74 protruding toward the first mold 60 is provided on the outer peripheral portion of the first face 72. The convex portion 74 is provided at a position that presses the outer peripheral portion of the first region 22a of the substrate 20 when the substrate 20 is installed in the first mold 60. The convex portion 74 also has a function of preventing the semiconductor element 10 and the first face 72 of the second mold 70 from coming into contact with each other when the substrate 20 on which the semiconductor element 10 is mounted is pressed.

The third mold 80 has a first face 82 facing the first face 62 of the first mold 60. The first face 82 has a frame-shaped first region for molding a face to which the lid body 40 is bonded, and a frame-shaped second region located inside the first region and having a convex portion 84 that protrudes toward the side of the first mold 60 more than the first region. The convex portion 84 corresponds to the concave portion 36 provided on the second face 34 of the frame body 30 and is provided at an end portion of the third mold 80 on the side of the second mold 70 (the side of the opening 86).

By closing the mold, the cavity 90 is formed inside the mold. At this time, since the second mold 70 has the convex portion 74, when the substrate 20 is pressed by the second mold 70, the cavity 90 is divided into a cavity (center cavity 92) in which the semiconductor element 10 is accommodated and a cavity (frame-shaped cavity 94) for molding the frame body 30. The central cavity 92 and the frame-shaped cavity 94 will be described later.

Further, the first mold 60 is provided with a gate 66 for injecting resin into a cavity inside the mold, and an air vent 68 for removing air expelled by the injected resin. Note that the gate 66 and the air vent 68 need only communicate with the frame-shaped cavity 94 in the mold into which the resin is injected and need not necessarily be disposed at the illustrated position of the first mold 60. The gate 66 and the air vent 68 are not necessarily provided in the first mold 60 and may be provided in the second mold 70 or the third mold 80.

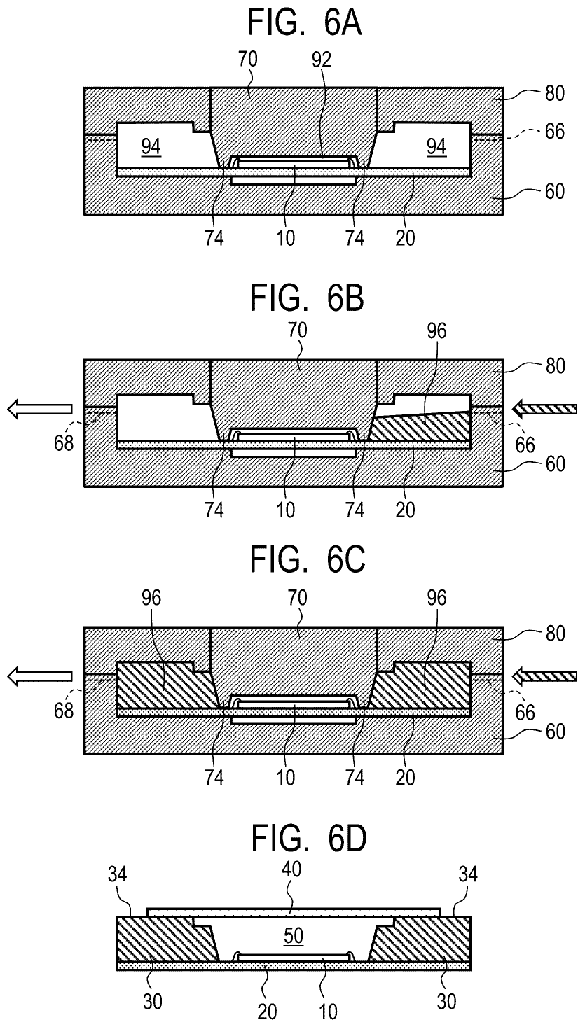

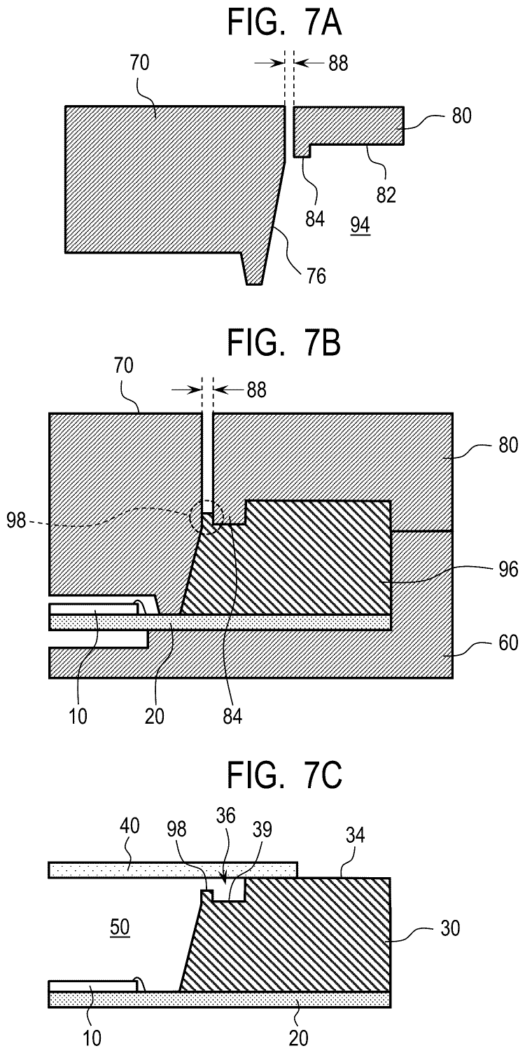

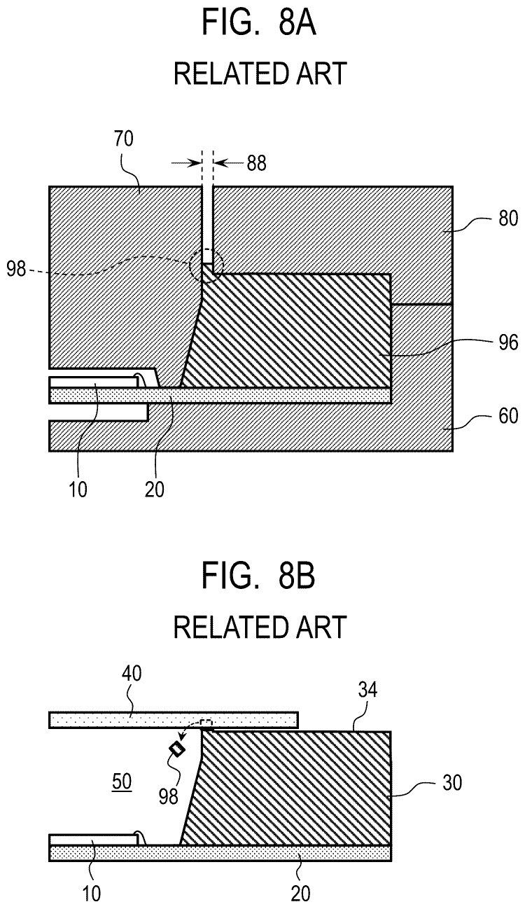

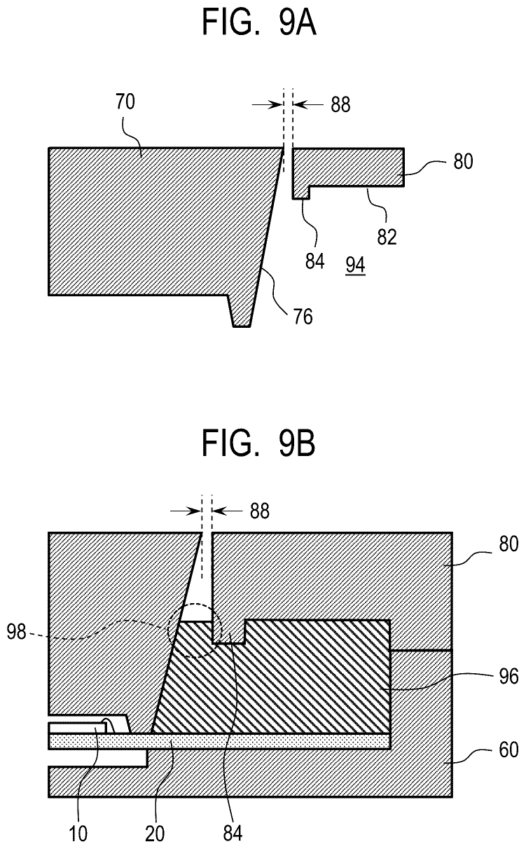

Next, a method of manufacturing the electronic component according to the present embodiment will be described with reference to FIG. 6A to FIG. 11B. FIG. 6A to FIG. 6D are cross-sectional views illustrating the method for manufacturing the electronic component according to the present embodiment. FIG. 7A to FIG. 7C are enlarged cross-sectional views illustrating the mold used in the method of manufacturing the electronic component according to the present embodiment and the structure of the frame body manufactured using the mold. FIG. 8A and FIG. 8B are diagrams for explaining a problem in a case where a convex portion is not provided in the third mold. FIG. 9A to FIG. 11B are enlarged cross-sectional views illustrating other examples of the mold used in the method of manufacturing the electronic component according to the present embodiment and the structure of the frame body manufactured using the mold.

First, the substrate 20 on which the semiconductor element 10 is mounted is installed in a mold including the first mold 60, the second mold 70, and the third mold 80. At this time, the second mold 70 is pushed in the −Z direction until the convex portion 74 comes into contact with the substrate 20, and the substrate 20 is sandwiched and fixed by the first mold 60 and the convex portion 74. Thus, the cavity 90 inside the mold is divided into the central cavity 92 and the frame-shaped cavity 94 by the convex portion 74 (FIG. 6A). Accordingly, it is possible to prevent the resin from leaking into the central cavity 92 from the frame-shaped cavity 94 at the time of injection molding described later.

In the present embodiment, the reason why the mold facing the first mold 60 is divided into the second mold 70 and the third mold 80 is to take into consideration that the thickness of the substrate 20 may vary. That is, when the substrate 20 is thinner than the design value, if the second mold 70 and the third mold 80 are integrated, separation of the frame-shaped cavity 94 and the central cavity 92 by the convex portion 74 becomes insufficient, and there is a possibility that the resin leaks from the frame-shaped cavity 94 into the central cavity 92. On the contrary, when the substrate 20 is thicker than the design value, if the second mold 70 and the third mold 80 are integrated with each other, the convex portion 74 may push the substrate 20 more than necessary, and the substrate 20 may be damaged. By dividing the mold facing the first mold 60 into the second mold 70 and the third mold 80, the height of the second mold 70 may be adjusted according to the thickness of the substrate 20, and leakage of the resin into the central cavity 92 and breakage of the substrate 20 may be effectively suppressed.

FIG. 7A is an enlarged view of a portion surrounded by a broken line in FIG. 4B or FIG. 5B. As illustrated in FIG. 7A, a gap 88 is provided between the second mold 70 and the third mold 80. By providing the gap 88 between the second mold 70 and the third mold 80, the second mold 70 may slide in the opening 86 of the third mold 80, and the height of the second mold 70 may be adjusted independently of the third mold 80. That is, the second mold 70 and the third mold 80 are separated from each other, and the distance between them and the first mold 60 may be changed independently of each other. However, if the gap 88 is too wide, there is a possibility that air escapes from the gap 88 and the shape accuracy of the resin deteriorates, and therefore, it is desirable to set the gap 88 to a minimum width necessary for the second mold 70 to slide. A suitable width of the gap 88 is, for example, about not less than 10 μm and not more than 50 μm.

Next, a resin 96 is injected into the frame-shaped cavity 94 from the gate 66 provided in the mold. The resin 96 injected from the gate 66 proceeds so as to fill the frame-shaped cavity 94. The air in the frame-shaped cavity 94 is pushed by the injected resin 96 and discharged from the air vent 68 (FIG. 6B and FIG. 6C). After the frame-shaped cavity 94 is filled with the resin 96, the resin 96 is cured, whereby the resin 96 becomes the frame body 30 having a shape corresponding to the shape of the frame-shaped cavity 94.

Next, the substrate 20 to which the frame body 30 is bonded is taken out from the mold, and the lid body 40 is bonded on the second face 34 of the frame body 30 so as to form the internal space 50 between the substrate 20 and the frame body 30, whereby the electronic component is completed (FIG. 6D and FIG. 7C).

When the resin 96 is injected, since the gap 88 exists between the second mold 70 and the third mold 80, the resin 96 may enter the gap 88 and remain as the convex portion 38 (burr 98) after the frame body 30 is molded (see FIG. 7B). Here, for example, as illustrated in FIG. 8A, assuming that the third mold 80 is not provided with the convex portion 84, the burr 98 protrudes in the Z direction beyond the height of the bonding face between the frame body 30 and the lid body 40. Therefore, the burr 98 may be chipped in the process of bonding the lid body 40 onto the second face 34 of the frame body 30, and may fall into the internal space 50, for example, as illustrated in FIG. 8B. When the chipped burr 98 becomes a foreign substance and adheres to the semiconductor element 10, it causes deterioration in characteristics and reliability of the electronic component 100, for example, in the case where the semiconductor element 10 is a photoelectric conversion element such as an imaging element, deterioration in image quality and the like.

In this regard, in the present embodiment, the convex portion 84 protruding in the −Z direction is provided at the end portion (the side of the opening 86) of the third mold 80 on the side facing the second mold 70. Therefore, even if the resin 96 enters the gap 88 between the second mold 70 and the third mold 80, the upper end portion of the burr 98 does not become higher than the second face 34 of the frame body 30 in the Z direction as long as the burr 98 does not exceed the height of the convex portion 84. Therefore, it is possible to reduce the possibility of chipping of the burr 98 in the process of bonding the lid body 40 onto the second face 34 of the frame body 30, and it is possible to suppress deterioration in characteristics and reliability of the electronic component 100.

The width of the convex portion 84 of the third mold 80 is not particularly limited, but is preferably not less than 0.1 mm and not more than 1.0. If the width of the convex portion 84 is less than 0.1 mm, the processing accuracy and durability of the mold may be affected. On the other hand, when the width of the convex portion 84 exceeds 1 mm, the contact area between the frame body 30 and the lid body 40 decreases, which may affect the adhesive strength of the lid body 40. The height of the convex portion 84 of the third mold 80 in the Z direction is preferably not less than 50 μm. When the height of the convex portion 84 is less than 50 μm, the upper end portion of the burr 98 becomes higher than the second face 34 of the frame body 30 in the Z direction, and chipping of the burr 98 may occur.

When focusing on the frame body 30 which is a molded article, the width of the concave portion 36 provided in the second face 34 of the frame body 30 is not particularly limited, but is preferably not less than 0.1 mm and not more than 1.0 mm. If the width of the concave portion 36 is less than 0.1 mm, the processing accuracy and durability of the mold may be affected. On the other hand, when the width of the concave portion 36 exceeds 1 mm, the contact area between the frame body 30 and the lid body 40 decreases, which may affect the adhesive strength. The difference between the height of the bonding face between the frame 30 and the lid body 40 and the height of the bottom 39 of the concave portion 36 is preferably not less than 50 μm. When the difference between the height of the bonding face between the frame body 30 and the lid body 40 and the height of the bottom 39 of the concave portion 36 is less than 50 μm, the upper end surface of the burr 98 becomes higher than the second face 34 of the frame body 30 in the Z direction, and chipping of the burr 98 may occur.

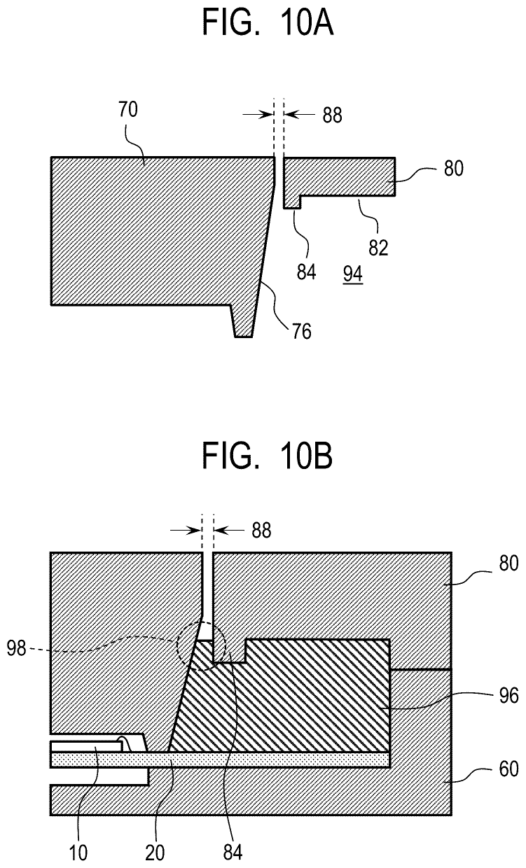

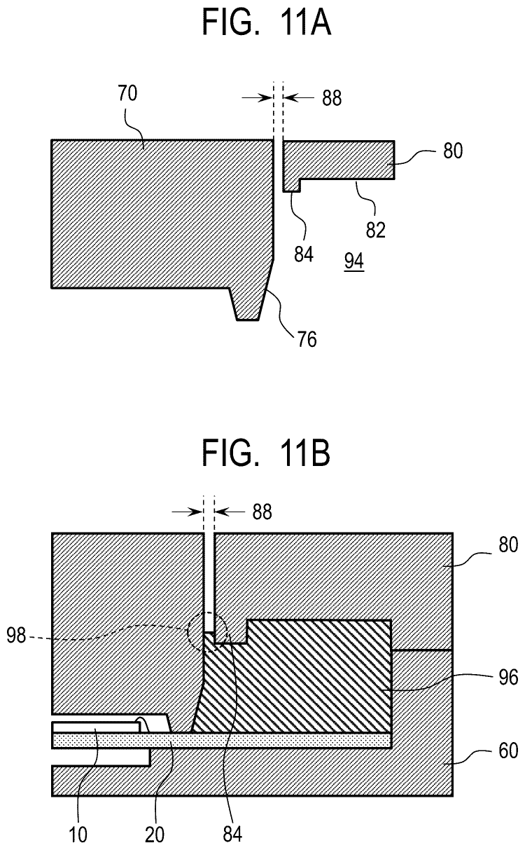

The second mold 70 preferably has a tapered shape in which the width in the X-Y plane gradually decreases toward the first face 72 facing the first mold 60. In this case, the tapered surface 76 of the second mold 70 may be provided over the entire outer surface as illustrated in FIG. 9A or may be provided on a part of the outer surface as illustrated in FIG. 7A, FIG. 10A, and FIG. 11A, for example. In this specification, the tapered surface refers to a portion of the outer surface of the second mold 70 that is inclined with respect to the normal direction of the first face 72.

However, when the tapered surface 76 is located in the opening 86 of the third mold 80 as illustrated in FIG. 9A and FIG. 10A, the width of the gap 88 on the side of the frame-shaped cavity 94 increases as illustrated in FIG. 9B and FIG. 10B, and thus the resin 96 entering the gap 88 increases. As a result, it may be difficult to stably control the height of the upper end portion of the burr 98 to be lower than the height of the first face 82 of the third mold 80 depending on the inclination angle of the tapered surface 76. From such a viewpoint, it is preferable that the tapered surface 76 of the second mold 70 is disposed closer to the first face 72 than the portion facing the inner side face of the third mold 80.

The width of the side of the first face 32 of the inner side face 33 of the frame body 30 molded using the second mold 70 having the tapered shape is narrower than the width of the side of the second face 34 of the inner side face 33 thereof. When the tapered surface 76 of the second mold 70 is disposed closer to the first face 72 than the portion facing the inner side face of the third mold 80, the width of the inner side face 33 of the frame 30 becomes gradually narrower in a portion closer to the second face 34 than the bottom of the concave portion 36.

As described above, according to the present embodiment, in the electronic component in which the electronic device is accommodated in the package in which the substrate and the resin frame are integrated with each other, it is possible to prevent the foreign matter generated from the package from being mixed, and it is possible to suppress the characteristic deterioration and the reliability deterioration of the electronic device.

### Second Embodiment

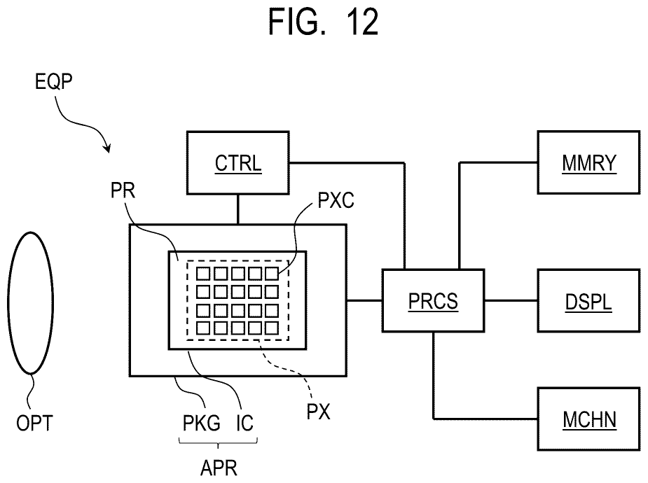

An equipment according to a second embodiment of the present invention will be described with reference to FIG. 12. FIG. 12 is a block diagram illustrating a schematic configuration of an equipment according to the present embodiment.

FIG. 12 is a schematic diagram illustrating an equipment EQP including a photoelectric conversion device APR. The photoelectric conversion device APR has the function of the electronic component 100 according to the first embodiment. All or part of the photoelectric conversion device APR is a semiconductor device IC (semiconductor element 10). The photoelectric conversion device APR of the present example may be used as, for example, an image sensor, an auto focus (AF) sensor, a photometric sensor, or a distance measurement sensor. The semiconductor device IC includes a pixel region PX in which pixel circuits PXC each including a photoelectric conversion unit are arranged in a matrix. The semiconductor device IC may include a peripheral region PR around the pixel region PX. A circuit other than the pixel circuit may be disposed in the peripheral region PR.

The photoelectric conversion device APR may have a structure (chip stacked structure) in which a first semiconductor chip provided with a plurality of photoelectric conversion units and a second semiconductor chip provided with peripheral circuits are stacked. Each of the peripheral circuits in the second semiconductor chip may be column circuits corresponding to pixel columns of the first semiconductor chip. The peripheral circuits in the second semiconductor chip may be matrix circuits corresponding to pixels or pixel blocks in the first semiconductor chip. As the connection between the first semiconductor chip and the second semiconductor chip, a through electrode (through silicon via (TSV)), an inter-chip interconnection by direct bonding of a conductor such as copper, a connection by a micro bump between chips, a connection by wire bonding, or the like may be employed.

The photoelectric conversion device APR may include a package PKG that accommodates the semiconductor device IC in addition to the semiconductor device IC. The package PKG may include a base body to which the semiconductor device IC is fixed, a lid body such as glass facing the semiconductor device IC, and connection members such as bonding wires or bumps for connecting terminals provided on the base body and terminal provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR as a photoelectric conversion device, and is, for example, a lens, a shutter, or a mirror. The control device CTRL controls the photoelectric conversion device APR, and is, for example, a semiconductor device such as an application specific integrated circuit (ASIC). The processing device PRCS processes a signal output from the photoelectric conversion device APR and constitutes an analog front end (AFE) or a digital front end (DFE). The processing unit PRCS is a semiconductor device such as a central processing unit (CPU) or an ASIC. The display device DSPL may be an electroluminescent (EL) display device or a liquid crystal display device that displays information (image) obtained by the photoelectric conversion device APR. The storage device MMRY may be a magnetic device or a semiconductor device that stores information (image) obtained by the photoelectric conversion device APR. The storage device MMRY may be a volatile memory such as an SRAM or a DRAM, or a nonvolatile memory such as a flash memory or a hard disk drive. The mechanical device MCHN may include a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, it is preferable that the equipment EQP further includes a storage device MMRY and a processing device PRCS separately from the storage circuit unit and the arithmetic circuit unit included in the photoelectric conversion device APR.

The equipment EQP illustrated in FIG. 12 may be an electronic device such as an information terminal (for example, a smartphone or a wearable terminal) having a photographing function or a camera (for example, an interchangeable lens camera, a compact camera, a video camera, and a monitoring camera). The mechanical device MCHN in the camera may drive components of the optical device OPT for zooming, focusing, and shutter operation. The equipment EQP may be a transportation device (movable object) such as a vehicle, a ship, or an airplane. The equipment EQP may be a medical device such as an endoscope or a CT scanner.

The mechanical device MCHN in the transport device may be used as a mobile device. The equipment EQP as a transport device is suitable for transporting the photoelectric conversion device APR, or for assisting and/or automating operation (manipulation) by an imaging function. The processing device PRCS for assisting and/or automating driving (manipulation) may perform processing for operating the mechanical device MCHN as a mobile device based on information obtained by the photoelectric conversion device APR.

The photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP.

### MODIFIED EMBODIMENTS

The present invention is not limited to the above-described embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present invention.

Further, in the first embodiment, it is assumed that the uppermost portion of the frame body 30 is the first region 34a serving as the bonding face between the frame body 30 and the lid body 40, but a region having a height in the Z direction higher than that of the first region 34a may be provided in a portion that does not interfere with the lid body 40 on the outer side face side of the first region 34a.

Further, although the photoelectric conversion element is assumed as the semiconductor element 10 in the first embodiment, the semiconductor element 10 does not necessarily need to be a photoelectric conversion element and may be another semiconductor element such as a semiconductor memory element.

It should be noted that the above-described embodiments are merely specific examples for carrying out the present invention, and the technical scope of the present invention should not be interpreted in a limited manner by these embodiments. That is, the present invention can be implemented in various forms without departing from the technical idea or the main features thereof.

Further, the disclosure of the present specification includes not only the matters described in the present specification but also all matters which may be grasped from the present specification and the drawings attached to the present specification. Also, the disclosure herein includes a complement of the concepts described herein. In other words, for example, when “A is larger than B” is described in this specification, it may be said that “A is not larger than B” is disclosed.

According to the present invention, in an electronic component in which a semiconductor element is accommodated in a package in which a circuit substrate and a resin frame body are integrated with each other, it is possible to prevent foreign matter generated from the package from being mixed, and to suppress deterioration in characteristics and reliability of the semiconductor element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-041053, filed Mar. 15, 2024, which is hereby incorporated by reference herein in its entirety.

What is claimed is:

1. An electronic component comprising:
a substrate provided with a semiconductor element;
a frame body provided over the substrate so as to surround a periphery of the semiconductor element; and
a lid body fixed to the frame body,
wherein the frame body has a first face in contact with the substrate and a second face facing the lid body,
wherein the second face of the frame body includes a first region of a frame-shape to which the lid body is bonded, a second region of a frame-shape located inside the first region and provided with a concave portion recessed toward the substrate, and a third region of a frame-shape located inside the second region and provided with a convex portion protruding toward the lid body,
wherein a height of the first region with respect to the substrate is higher than a height of the second region with respect to the substrate,
wherein a side face of the frame body is located outside a side face of the lid body in a cross-sectional view of the electronic component, and
wherein a height of a tip portion of the convex portion with respect to the substrate is lower than a height of a bonding face between the frame body and the lid body with respect to the substrate and is higher than a height of a bottom of the concave portion with respect to the substrate.

2. The electronic component according to claim 1, wherein the concave portion is provided so as to surround the third region in a plan view.

3. The electronic component according to claim 1, wherein the third region is in contact with an inner side face of the frame body.

4. The electronic component according to claim 1, wherein a width of the concave portion is not less than 0.1 mm and not more than 1.0 mm.

5. The electronic component according to claim 1, wherein a difference between the height of the bonding face and the height of the bottom of the concave portion is not less than 50 μm.

6. The electronic component according to claim 1, wherein a width of an inner side face of the frame body on a side of the first face is narrower than a width of the inner side face on a side of the second face.

7. The electronic component according to claim 6, wherein a width of the inner side face is gradually reduced in a portion closer to the first face than a bottom of the concave portion.

8. The electronic component according to claim 1,
wherein the semiconductor element is a photoelectric conversion element, and
wherein the lid body is formed of a light-transmissive member.

9. The electronic component according to claim 1, wherein the substrate further includes an electronic element provided on a face opposite to a face on which the semiconductor element is provided.

10. A method of manufacturing an electronic component comprising:
forming a frame body over a substrate provided with a semiconductor element so as to surround a periphery of the semiconductor element; and
fixing a lid body to the frame body so as to close a space in which the semiconductor element is provided,
wherein, in the forming the frame body, the frame body is formed by an injection molding using a first mold configured to place the substrate, a second mold configured to mold an inner face of the frame body, and a third mold configured to mold a face of the frame body facing the lid body,
wherein the second mold and the third mold are separated from each other, and are enabled to change a distance to the first mold independently of each other, and
wherein the third mold includes a first region of a frame shape configured to mold a face to which the lid body is bonded, and a second region of a frame shape located inside the first region and having a convex portion protruding toward the first mold more than the first region.

11. The method of manufacturing an electronic component according to claim 10, wherein the convex portion is provided at an end portion of the third mold on a side of the second mold.

12. The method of manufacturing an electronic component according to claim 10, wherein a width of the convex portion of the third mold is not less than 0.1 mm and not more than 1.0 mm.

13. The method of manufacturing an electronic component according to claim 10, wherein a height of the convex portion of the third mold is not less than 50 μm.

14. The method of manufacturing an electronic component according to claim 10, wherein the second mold includes a taper shape in which a width on a side of the first mold is narrower than a width on a side of the third mold.

15. The method of manufacturing an electronic component according to claim 14, wherein the taper shape is provided closer to the first mold than a portion where the second mold and the third mold face each other.

16. The method of manufacturing an electronic component according to claim 10, wherein a gap of not less than 10 μm and not more than 50 μm is provided between the second mold and the third mold.

17. The method of manufacturing an electronic component according to claim 10, wherein the second mold includes a protruding portion of a frame-shape protruding toward the substrate provided on an outer peripheral portion of a face facing the substrate, and is configured to be separated from the semiconductor element when the protruding portion is in contact with the substrate.

18. The method of manufacturing an electronic component according to claim 10,
wherein a height of the first region with respect to the substrate is higher than a height of the second region with respect to the substrate, and
wherein a side face of the frame body is located outside a side face of the lid body in a cross-sectional view of the electronic component.

19. An equipment comprising:
the photoelectric conversion device according to claim 1; and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
